(19) United States
(12) Patent Application Publication
(10) Pub. No.: US 2013/0092426 A1
(43) Pub. Date: Apr. 18, 2013

(54) ANISOTROPIC CONDUCTIVE FILM AND FABRICATION METHOD THEREOF

(71) Applicant: Industrial Technology Research Institute, Hsinchu (TW)

(72) Inventors: Tung-Chuan WU, Hsinchu City (TW); Min-Chieh CHOU, Taipei City (TW)

(73) Assignee: Industrial Technology Research Institute, Hsinchu (TW)

(21) Appl. No.: 13/653,364

(22) Filed: Oct. 16, 2012

(30) Foreign Application Priority Data
Oct. 17, 2011 (TW) 100137471

(51) Int. Cl. H05K 1/09; B44C 1/22; B05D 5/12

(52) U.S. Cl. 174/257; 427/58; 427/510; 216/18

(57) ABSTRACT

An embodiment of the disclosure provides an anisotropic conductive film including an insulating substrate and a plurality of conductive polymer pillars. The insulating substrate has a first surface and a second surface. Each of the conductive polymer pillars passes through the insulating substrate and is exposed at the first surface and the second surface, and the conductive polymer pillars include an intrinsically conducting polymer.

### CROSS REFERENCE TO RELATED APPLICATIONS

This application claims priority of Taiwan Patent Application No. 100137471, filed on Oct. 17, 2011, the entirety of which is incorporated by reference herein.

### BACKGROUND OF THE DISCLOSURE

1. Field of the Disclosure

The present disclosure relates to conductive films, and in particular relates to anisotropic conductive films and manufacturing methods thereof.

2. Description of the Related Art

In recent years, with demand for light, thin, and portable, flexible electronic devices, such as electronic paper/flexible displays, have become an important research issue for international companies and research institutions.

Manufacturing processes of present flexible displays usually use an anisotropic conductive film (ACF) to bond flexible display modules to thinned driver chips or flexible driver circuit boards. Anisotropic conductive films commonly used substantially include pressure sensitive anisotropic conductive films and thermosetting type anisotropic conductive films.

The pressure sensitive anisotropic conductive film includes an insulating polymer material with high elasticity and doped with conductive particles, and the conductivity of the pressure sensitive anisotropic conductive film is sensitive to pressure. If the pressure sensitive anisotropic conductive film is used as a medium for electric connection, a pressure to the pressure sensitive anisotropic conductive film is needed to be applied continuously for the conductive particles to be electrically connected to each other. If the applied pressure diminishes or disappears, the conductive particles are separated from each other by the insulating polymer material with high elasticity, and the pressure sensitive anisotropic conductive film loses the electrically-conducting function as a result. Therefore, the conductive property of the pressure sensitive anisotropic conductive film is unstable as the pressure applied to the pressure sensitive anisotropic conductive film changes, so the pressure sensitive anisotropic conductive film is not suitable for use in the flexible electronic displays, such as electronic paper/flexible displays.

The thermosetting type anisotropic conductive film is formed of a thermosetting type insulating polymer material doped with conductive particles. When the thermosetting type anisotropic conductive film is used to bond two electronic devices, it needs to apply a high pressure (40-150 MPa) and a high temperature (140-230° C.) to proceed with a thermal curing bonding package process for the conductive particles to be fixed between the pads of the two electronic devices. Therefore, the use of the thermosetting type anisotropic conductive film for the bonding process is easily limited by high pressure destruction and thermal deformation. Furthermore, to ensure a low contact resistance, in each joint, there must be a sufficient number of conductive particles to be pressed between the top pad and the lower pad, so the density of the conductive particles must be high enough. However, if the density of the conductive particles is too high, the neighboring electrodes are easily shorted. Therefore, the pitch between the neighboring electrodes can not be less than 30 μm, which will not satisfy the demand of future driver chips that require the pitch between the pad electrodes to be less than 20 μm.

### SUMMARY OF THE DISCLOSURE

An embodiment of the disclosure provides a anisotropic conductive film which includes: an insulating substrate having a first surface and a second surface; and a plurality of conductive polymer pillars, wherein each of the conductive polymer pillars passes through the insulating substrate and is exposed at the first surface and the second surface, and the conductive polymer pillars include an intrinsically conducting polymer.

An embodiment of the disclosure provides a manufacturing method of an anisotropic conductive film, which includes: providing an insulating substrate having a first surface and a second surface; forming a plurality of through holes in the insulating substrate, wherein each of the through holes passes through the first surface and the second surface; filling a conductive polymer material in the through holes; and curing the conductive polymer material to form a plurality of conductive polymer pillars in the through holes.

A detailed description is given in the following embodiments with reference to the accompanying drawings.

### BRIEF DESCRIPTION OF THE DRAWINGS

The present disclosure can be more fully understood by reading the subsequent detailed description and examples with references made to the accompanying drawings, wherein:

FIG. 1 is a cross-sectional view of an anisotropic conductive film according to an embodiment of the present disclosure;

FIGS. 2-5 are cross-sectional views of variations of the anisotropic conductive film of FIG. 1;

FIG. 6A to FIG. 6E are cross-sectional views of a manufacturing process of an anisotropic conductive film according to an embodiment of the present disclosure;

FIG. 7A to FIG. 7C are cross-sectional views of a manufacturing process of an anisotropic conductive film according to another embodiment of the present disclosure; and

FIG. 8A to FIG. 8D are cross-sectional views of a manufacturing process of an anisotropic conductive film according to still another embodiment of the present disclosure.

### DETAILED DESCRIPTION OF THE DISCLOSURE

The following description is of the embodiments of carrying out the disclosure. This description is made for the purpose of illustrating the general principles of the disclosure and should not be taken in a limiting sense. The scope of the disclosure is determined by reference to the appended claims.

It is understood, that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

The anisotropic conductive film of the present disclosure has a plurality of conductive polymer pillars passing through an insulating substrate, wherein the conductive polymer pillars are entirely formed of a conductive material, so electronic devices may be electrically connected to each other through the conductive polymer pillars simply by disposing the electronic devices on top and bottom sides of the anisotropic conductive film. Compared to conventional pressure sensitive anisotropic conductive films, the anisotropic conductive film of the present disclosure does not need pressure to be applied to have conductivity. Compared to conventional thermosetting type anisotropic conductive films, the anisotropic conductive film of the present disclosure does not need to proceed with a thermal curing process to fix the conductive particles.

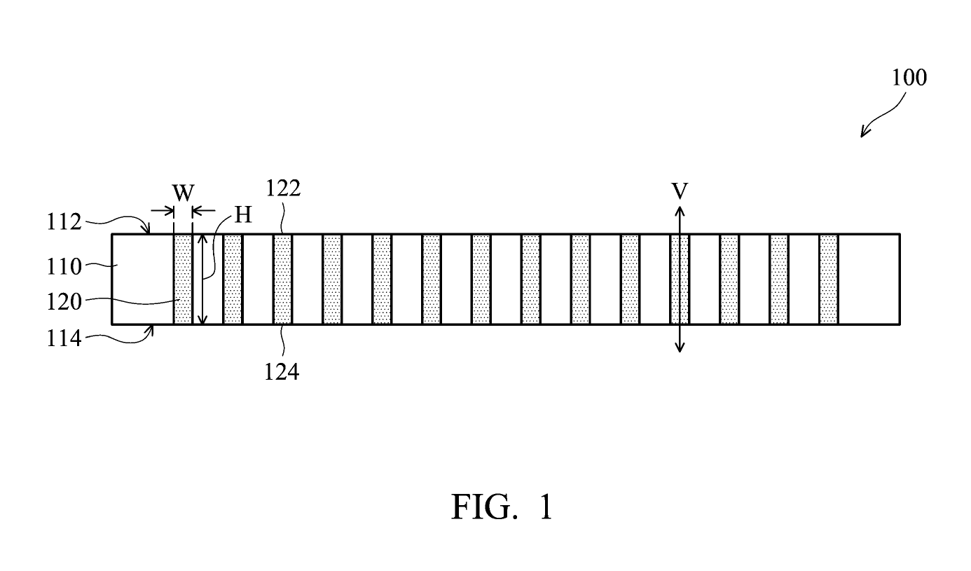

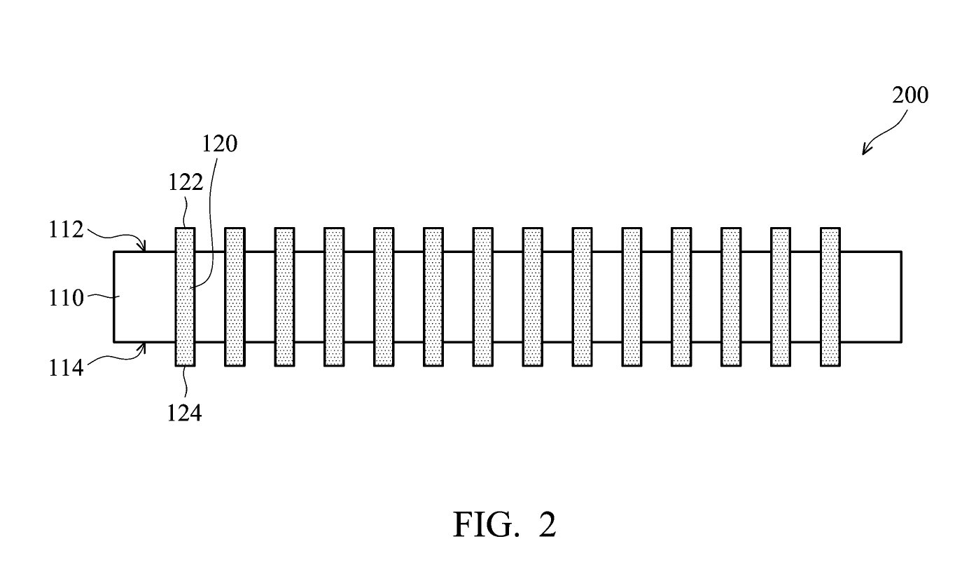

FIG. 1 is a cross-sectional view of an anisotropic conductive film according to an embodiment of the present disclosure. FIGS. 2-5 are cross-sectional views of variations of the anisotropic conductive film of FIG. 1.

Referring to FIG. 1, the anisotropic conductive film 100 of the present embodiment includes an insulating substrate 110 and a plurality of conductive polymer pillars 120. The insulating substrate 110 has a first surface 112 and a second surface 114 opposite thereto, and each of the conductive polymer pillars 120 passes through the insulating substrate 110 and is exposed at the first surface 112 and the second surface 114.

Because the anisotropic conductive film 100 has the conductive polymer pillars 120 passing through the insulating substrate 110, two electronic devices (not shown) to be electrically connected may be connected to each other through the conductive polymer pillars 120. Specifically, the two electronic devices are disposed on the first surface 112 and the second surface 114, and pads of the two electronic devices are opposite to each other and respectively contact two opposite ends of the same conductive polymer pillar 120, such that the two electronic devices may be connected to each other through the conductive polymer pillar 120.

The conductive polymer pillars 120 include an intrinsically conducting polymer. For example, depending on the specific application needs, the conductive polymer pillars 120 may be formed of the intrinsically conducting polymer, or the intrinsically conducting polymer and a plurality of conductive particles doped therein, or a mixture of the intrinsically conducting polymer and other suitable materials.

In an embodiment, the volume percentages of the intrinsically conducting polymer and the conductive particles doped therein in the conductive polymer pillars 120 are greater than 50 vol % and less than 50 vol %, respectively.

In another embodiment, depending on the specific application needs, additives may be added in the conductive polymer pillars 120 for the conductive polymer pillars 120 to have various properties, wherein the additives are, for example, curing agents (e.g., 3-(Trimethoxysilyl)propyl acrylate) or emulsifiers (e.g., Poly(ethylene glycol)). The weight ratio of the intrinsically conducting polymer to the additives may be adjusted arbitrarily, wherein the conductive polymer pillars 120 have an integral surface resistivity of less than 500 ohm/square (Ω/□). In general, the content of the additives is less than 10 parts by weight based on 100 parts by weight of the intrinsically conducting polymer.

It should be noted that the term “intrinsically conducting polymer” means a polymer material without doping with other materials and being conductive per se. For example, the intrinsically conducting polymer may be poly(3,4-ethylenedioxythiophene)-poly(styrenesulfonate), polyacetylene, polyaniline, polypyrrole, polythiophene, or combinations thereof, or other suitable intrinsically conducting polymer materials. In one embodiment, a density of the intrinsically conducting polymer with poly(3,4-ethylenedioxythiophene)-poly(styrenesulfonate) is about 1.011 g/cm³ at 25° C.

In one embodiment, the conductive particles are, for example, gold particles, silver particles, nickel particles, carbon black particles, graphite particles, carbon nanoballs, carbon nanotubes, combinations thereof, or other suitable conductive particles. Diameters of the conductive particles may range from 0.01 μm to 60 μm.

In one embodiment, the insulating substrate 110 includes a polymer material, for example, thermoplastic amorphous or semi-crystalline polyethylene terephthalate (PET), highly elastic silicone rubber, thermosetting polyimide (PI), or other suitable insulating polymer materials.

It should be noted that because the insulating substrate 110 and the conductive polymer pillars 120 may both include a polymer material, they may have similar elasticity, which avoids the problem that the conductive pillars are easily peeled off from the substrate during bending of the anisotropic conductive film 100. It can be known that the anisotropic conductive film 100 has good flexing resistance. Therefore, the anisotropic conductive film 100 is suitable for use in displays with flexibility, such as electronic paper/flexible displays.

In one embodiment, each of the conductive polymer pillars 120 has a height H to width W ratio (i.e. aspect ratio) of, for example, larger than 1, and major axis directions V of the conductive polymer pillars 120 may be substantially parallel to a normal vector of the first surface 112 or the second surface 114. In other embodiments, the major axis directions of the conductive polymer pillars (not shown) may not be parallel to a normal vector of the first surface 112 (or the second surface 114), or the conductive polymer pillars may be in a curved shape or in other non-linear shapes. In one embodiment, the cross-sections of the conductive polymer pillars 120 are in a circular shape, a rectangular shape, a triangular shape, or other polygonal shapes.

In the present embodiment, a first end 122 and a second end 124 of each of the conductive polymer pillars 120 are substantially aligned with the first surface 112 and the second surface 114 respectively. In other embodiments, referring to FIG. 2, a first end 122 and a second end 124 of each of the conductive polymer pillars 120 of the anisotropic conductive film 200 may respectively protrude from the first surface 112 and the second surface 114. Therefore, when the anisotropic conductive film 200 is employed to connect to two electronic devices (not shown), the protruding first end 122 and the protruding second end 124 may directly contact pads of the two electronic devices to improve the process yield of electrical connection of the two electronic devices.

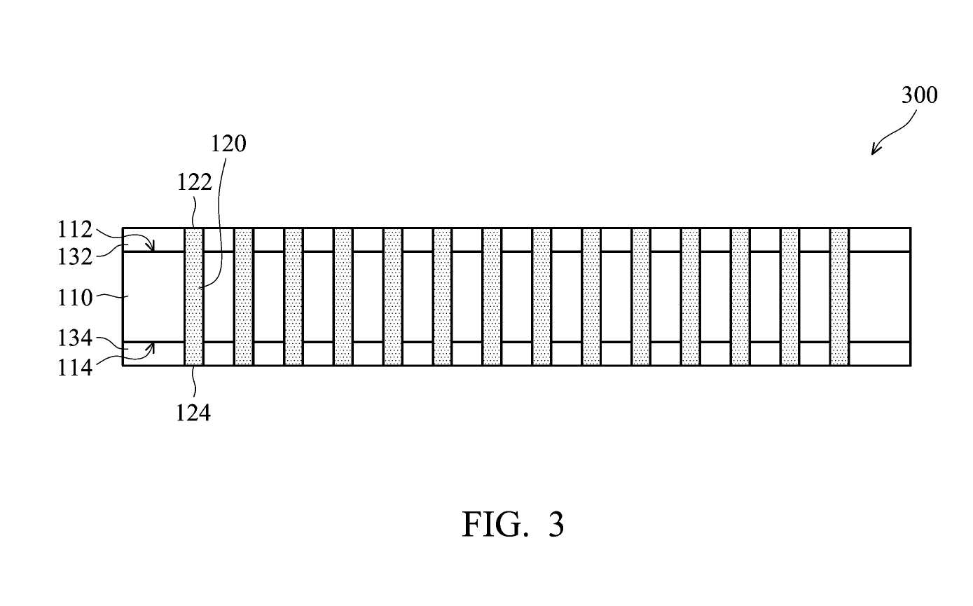

As shown in FIG. 3, the insulating substrate 110 may include glue with adhesion property in room temperature, for example, acrylic glue with adhesion in room temperature (such as glue formed by copolymerization and crosslink of n-butyl acrylate, 2-ethylhexyl acrylate, and acrylic acid). To prevent the insulating substrates 110 from adhering to each other during storing of the insulating substrates 110 in a stack or in a roll, a first release film 132 may be optionally disposed on the first surface 112 of each of the insulating substrates 110. The first end 122 of each of the conductive polymer pillars 120 in the present embodiment may optionally pass through the first release film 132, but it may not limit herein. For simplicity sake, FIG. 3 merely depicts an insulating substrate 110.

To prevent the second surface 114 of the insulating substrate 110 from adhering to foreign objects before using the insulating substrate 110, a second release film 134 may be optionally formed on the second surface 114 of the insulating substrates 110. In the present embodiment, the second end 124 of each of the conductive polymer pillars 120 may optionally pass through the second release film 134, but it may not limit herein. The first release film 132 and the second release film 134 may include a non-adhesive insulating polymer, such as polyimide (PI). In the present embodiment, the conductive polymer pillars 120 may be formed of the intrinsically conducting polymer, or the intrinsically conducting polymer and a plurality of conductive particles doped therein, a mixture of the intrinsically conducting polymer and other suitable materials, or composite conductive polymer materials including polyvinyl pyrrolidone doped with conductive particles, polyvinyl alcohol doped with conductive particles, etc.

When an anisotropic conductive film 300 as shown in FIG. 3 is being used, the first release film 132 and the second release film 134 need to be removed to expose the insulating substrate 110 with adhesion. Because the insulating substrate 110 has an adhesive property, electronic devices (not shown) disposed on a top side and a lower side of the insulating substrate 110 may be bonded to the insulating substrate 110 at room temperature. Compared to the conventional thermosetting type anisotropic conductive films, a thermal curing process does not need to be performed to the anisotropic conductive film of the embodiment.

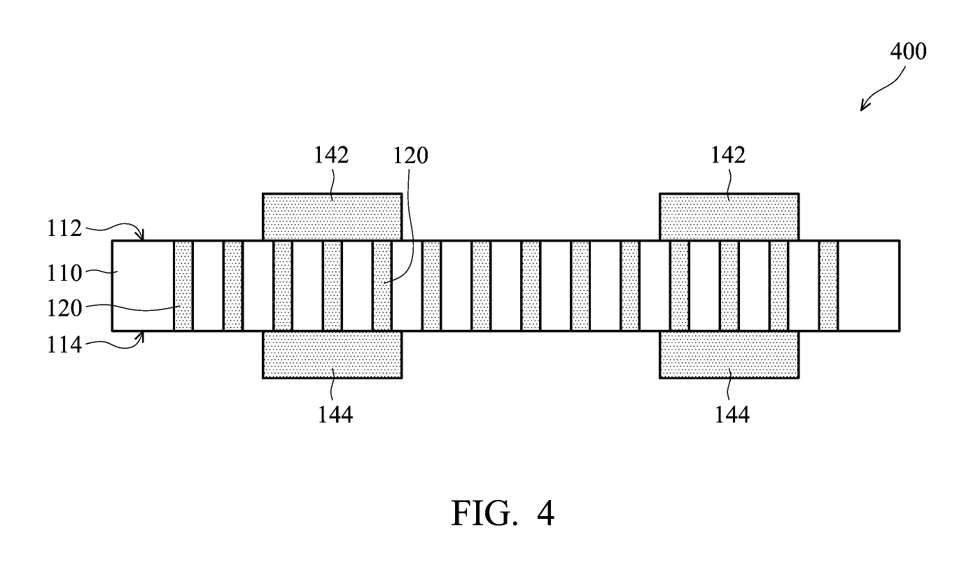

Furthermore, referring to FIG. 4, an anisotropic conductive film 400 may further include a plurality of first conductive pads 142 and a plurality of second conductive pads 144. The first conductive pads 142 are disposed on the first surface 112 and connect a plurality of conductive polymer pillars 120, and the second conductive pads 144 are disposed on the second surface 114 and connect the conductive polymer pillars 120 to electrically connect the first conductive pads 142. In other embodiments not shown, the first conductive pad 142 and the second conductive pad 144 may connect one conductive polymer pillar and electrically connect to each other through the conductive polymer pillar.

It should be noted that the anisotropic conductive film 400 may be used as a probe card, and in this case, the first conductive pad 142 (or the second conductive pad 144) may be used as a probe head.

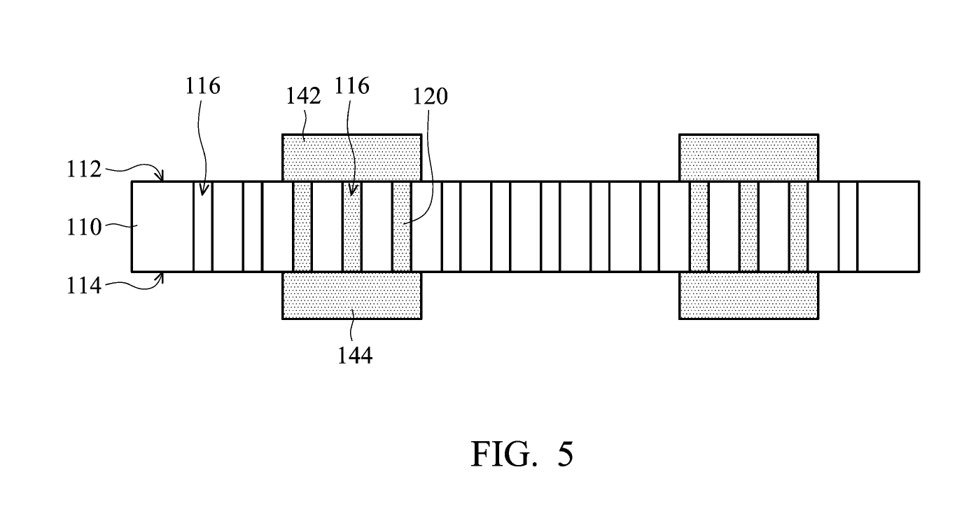

Referring to FIG. 5, in another embodiment, the insulating substrate 110 may have a plurality of through holes 116, and the conductive polymer pillars 120 are formed in the through holes 116 between the first conductive pads 142 and the second conductive pads 144, wherein the other through holes 116 (which are not between the first conductive pads 142 and the second conductive pads 144) are hollow. In the present embodiment, the first conductive pads 142, the second conductive pads 144, and the conductive polymer pillars 120 therebetween are formed integrally.

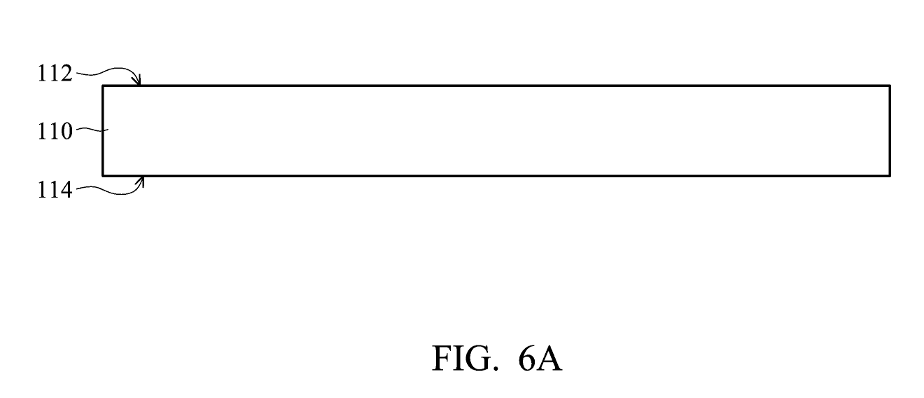

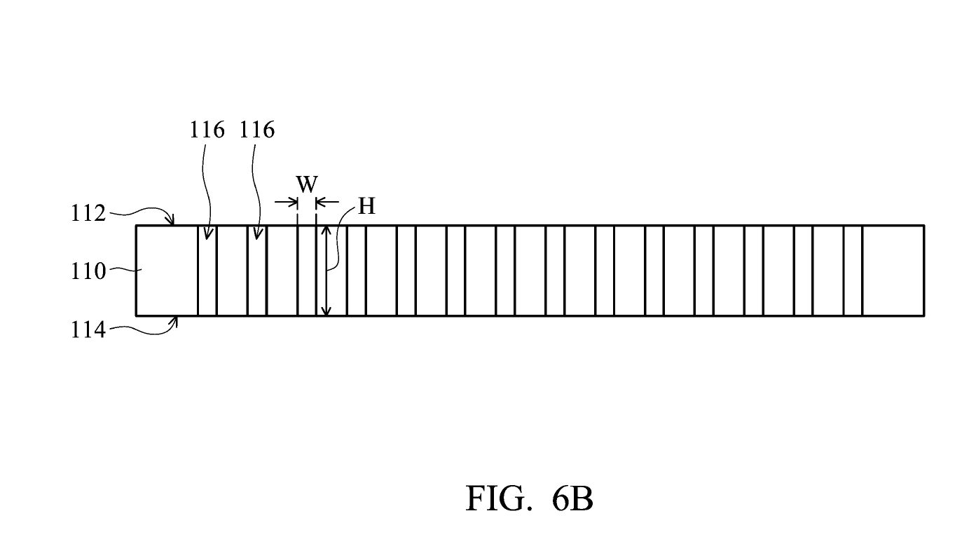

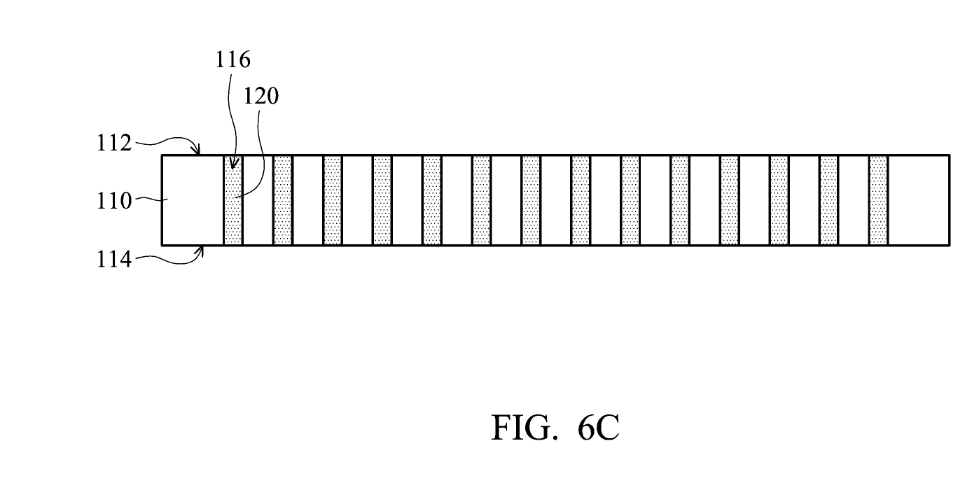

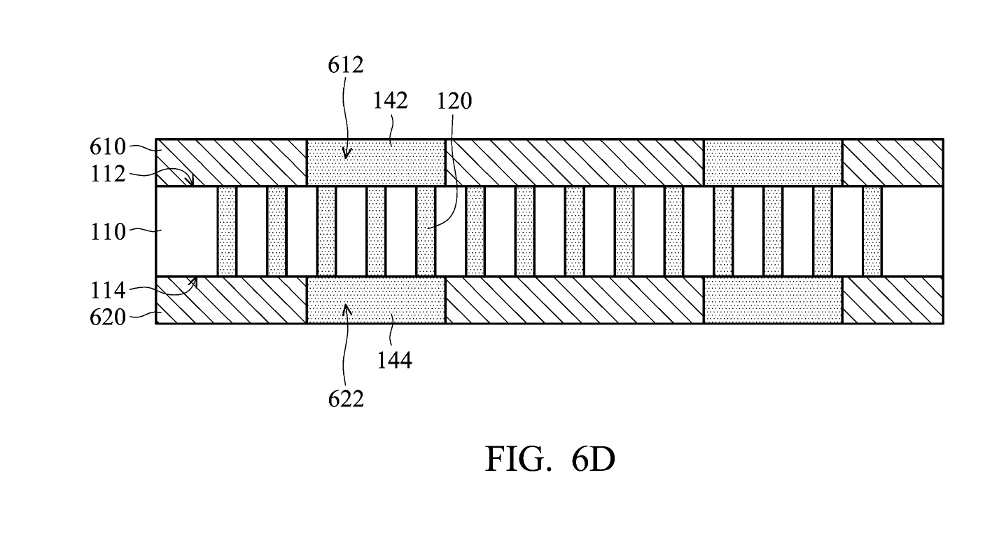

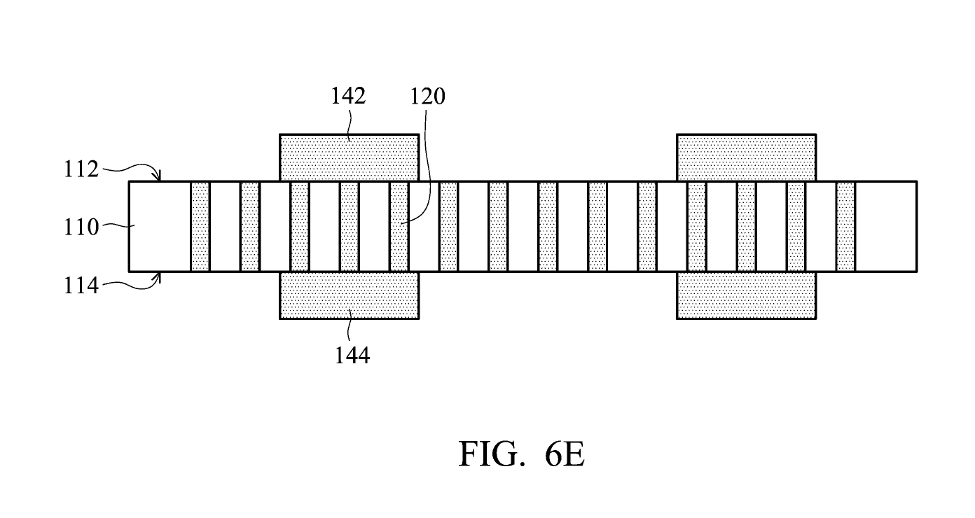

FIG. 6A to FIG. 6E are cross-sectional views of a manufacturing process of an anisotropic conductive film according to an embodiment of the present disclosure.

Referring to FIG. 6A, an insulating substrate 110 is provided and has a first surface 112 and a second surface 114. Then, depending on the specific application needs, a hydrophobic treatment may be applied to the first surface 112 and the second surface 114. The hydrophobic treatment includes, for example, using an atmosphere plasma to deposit an hydrophobic layer (not shown) with a thickness of 40-60 nm on the first surface 112 and the second surface 114 of the insulating substrate 110 by using fluoroalkylsilane as a precursor.

Referring to FIG. 6B, a plurality of through holes 116 are formed in the insulating substrate 110, wherein each of the through holes 116 passes through the first surface 112 and the second surface 114. In the present embodiment, the forming method of the through holes 116 includes energy beam drilling or machining, wherein the energy beam drilling includes, for example, laser beam drilling, electron beam drilling, or ion beam drilling. A diameter of the through hole 116 is, for example, about 1-100 μm, and a height H to width W ratio of the through hole 116 is, for example, larger than 1.

Referring to FIG. 6C, a conductive polymer material is filled in the through holes 116, and is cured to form a plurality of conductive polymer pillars 120 in the through holes 116. The filling process of the conductive polymer material includes, for example, an immersion method. The curing process of the conductive polymer material includes, for example, a thermal curing method or a light curing method (such as UV curing method). In the present embodiment, the conductive polymer pillars 120 may be formed of the intrinsically conducting polymer, or the intrinsically conducting polymer and a plurality of conductive particles doped therein, a mixture of the intrinsically conducting polymer and other suitable materials (such as curing agents or emulsifiers), or composite conductive polymer materials including polyvinyl pyrrolidone doped with conductive particles and curing agents, polyvinyl alcohol doped with conductive particles and curing agents, etc.

For example, the insulating substrate 110 with the through holes 116 is dipped in the liquid conductive polymer material, wherein the liquid conductive polymer material may be formed of the intrinsically conducting polymer (or the intrinsically conducting polymer and a plurality of conductive particles doped therein) and a solvent, and the conductive polymer material may be fully filled in the through holes 116 by vacuum pumping. After fully filling the through holes 116 with the conductive polymer material, the insulating substrate 110 is taken out from the liquid conductive polymer material, and the conductive polymer material remaining on the surface of the insulating substrate 110 is cleaned up. Then, the conductive polymer material in the through holes 116 is heated to a suitable temperature (such as 80-130° C.) so as to evaporate the solvent of the conductive polymer material, and may be further heated to fully cure the conductive polymer material depending on materials.

Because the cured conductive polymer material may be changed in size, the process described above (i.e., the dipping of the insulating substrate 110 in the liquid conductive polymer material and the curing process) may be repeated to make sure that the cured conductive polymer material may be fully filled in the through holes 116.

Referring to FIG. 6D, a screen printing process may be optionally performed to form a plurality of first conductive pads 142 and a plurality of second conductive pads 144 on the first surface 112 and the second surface 114 respectively, wherein the first conductive pad 142 electrically connects to the second conductive pad 144 through the conductive polymer pillars 120.

Specifically, a screen 610 with a plurality of openings 612 and a screen 620 with a plurality of openings 622 are disposed on the first surface 112 and the second surface 114 respectively, wherein the openings 612 and 622 may expose one or more than one conductive polymer pillar 120 at the same time. Then, the liquid conductive polymer material is filled in the openings 612 and 622. The screen printing process may be performed in vacuum to make sure that the conductive polymer material may be fully filled in the openings 612 and 622. Then, the conductive polymer material is thermally cured to form a plurality of first conductive pads 142 and a plurality of second conductive pads 144.

Referring to FIG. 6E, the screens 610 and 620 are removed.

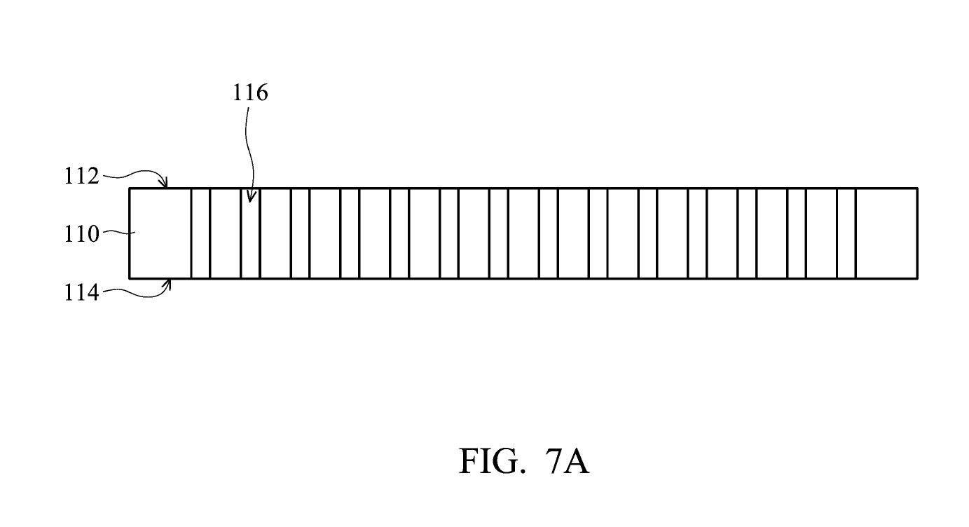

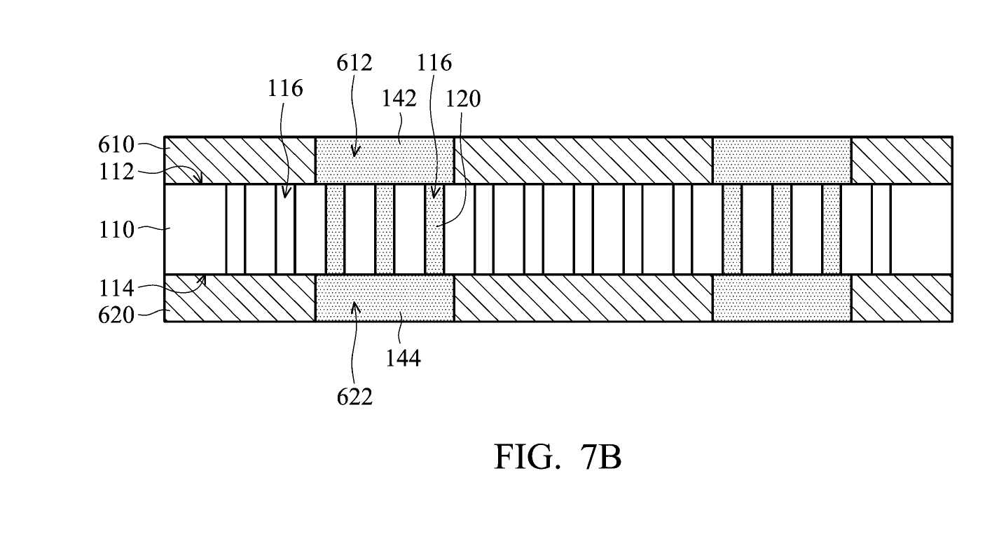

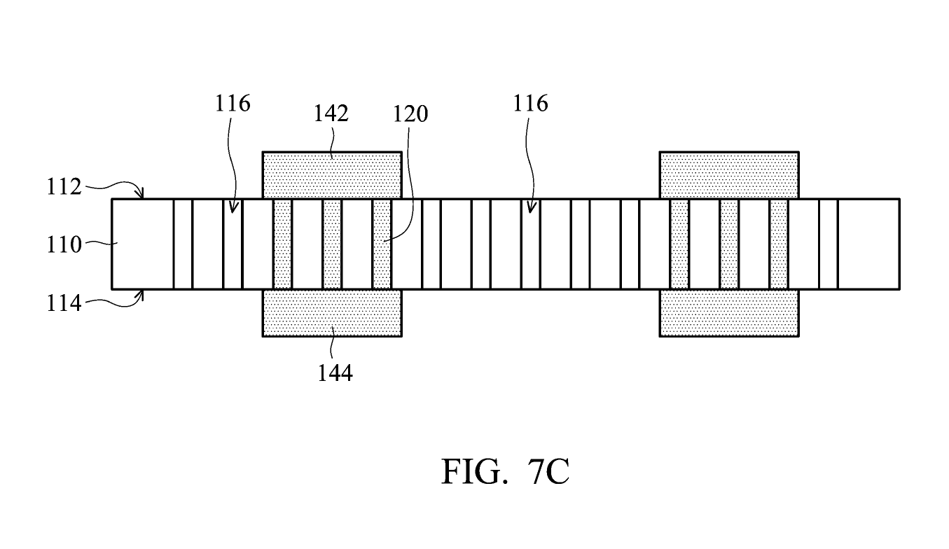

FIG. 7A to FIG. 7C are cross-sectional views of a manufacturing process of an anisotropic conductive film according to another embodiment of the present disclosure.

Referring to FIG. 7A, an insulating substrate 110 is provided and has a first surface 112 and a second surface 114. Then, a plurality of through holes 116 are formed in the insulating substrate 110, wherein each of the through holes 116 passes through the first surface 112 and the second surface 114.

Referring to FIG. 7B, a screen 610 with a plurality of openings 612 and a screen 620 with a plurality of openings 622 are disposed on the first surface 112 and the second surface 114 respectively. The openings 612 and 622 may expose one or more through holes 116 at the same time, and the screens 610 and 620 may cover one or more through holes 116. Then, the liquid conductive polymer material may be filled in the openings 612 and 622 and the through holes 116 exposed by the openings 612 and 622. Then, the conductive polymer material is cured by heating or illumination to form a plurality of first conductive pads 142, a plurality of second conductive pads 144, and a plurality of conductive polymer pillars 120.

Referring to FIG. 7C, the screens 610 and 620 are removed.

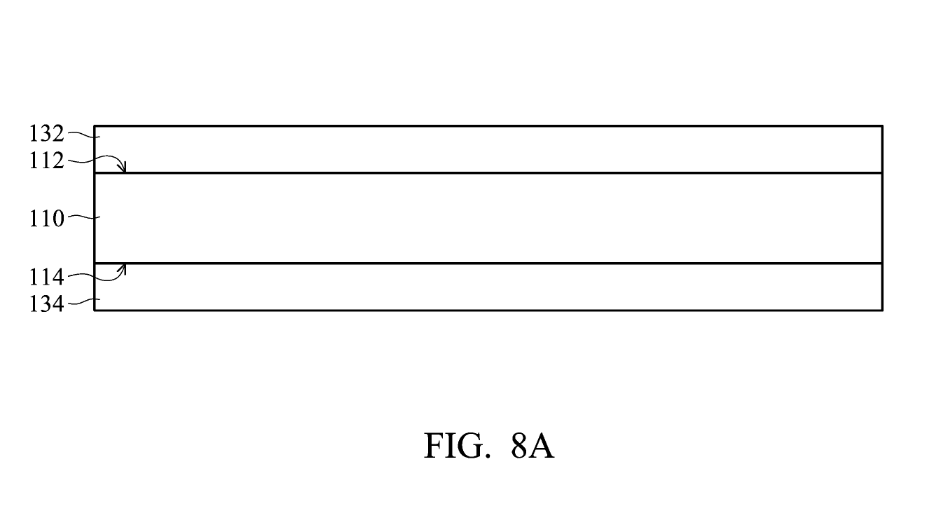

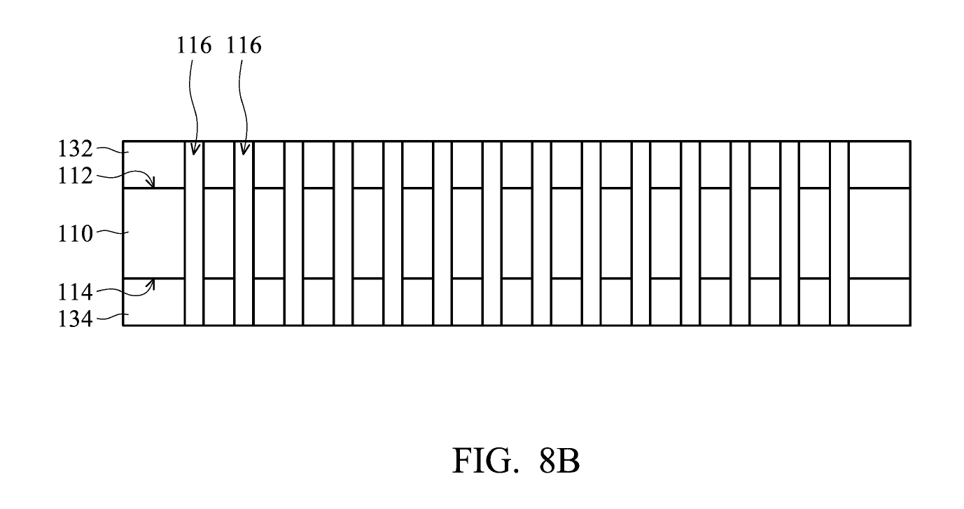

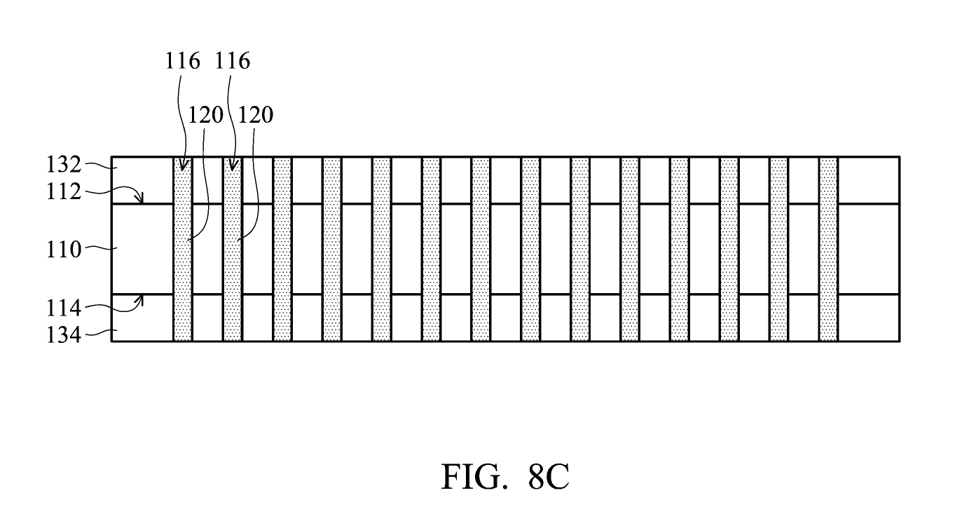

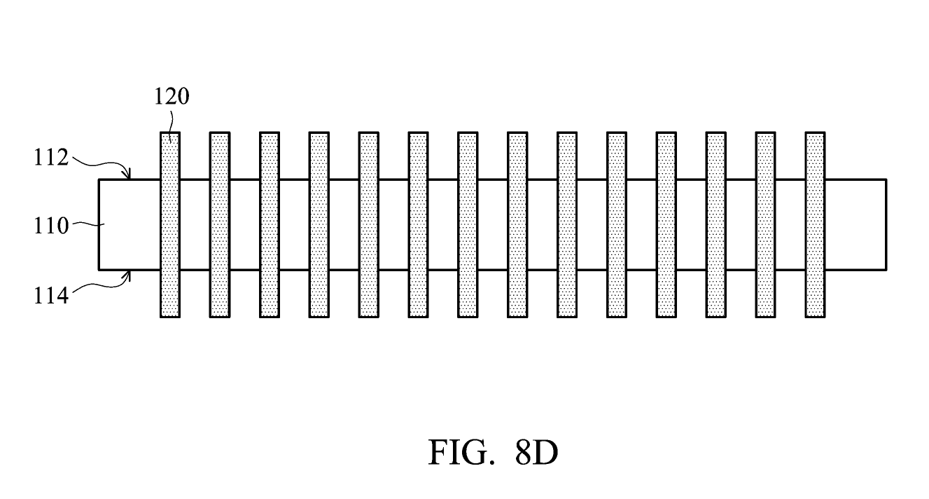

FIG. 8A to FIG. 8D are cross-sectional views of a manufacturing process of an anisotropic conductive film according to still another embodiment of the present disclosure.

Referring to FIG. 8A, an insulating substrate 110 is provided, and a first release film 132 and a second release film 134 are formed on a first surface 112 and a second surface 114 of the insulating substrate 110 respectively. The insulating substrate 110 may include glue with adhesion property in room temperature

Referring to FIG. 8B, a plurality of through holes 116 passing through the insulating substrate 110, the first release film 132 and the second release film 134 are formed, wherein each of the through holes 116 passes through the first surface 112 and the second surface 114.

Referring to FIG. 8C, a conductive polymer material may be filled in the through holes 116 and may be cured to form a plurality of conductive polymer pillars 120 in the through holes 116.

Referring to FIG. 8D, the first release film 132 and the second release film 134 may depend on needs to be removed.

In light of the aforementioned description, the anisotropic conductive film of the present disclosure electrically connects the electronic devices through a plurality of conductive polymer pillars passing through the insulating substrate, so the anisotropic conductive film of the present disclosure does not need pressure to be applied to have conductivity and does not need to proceed with a thermal curing process to fix the conductive particles. Furthermore, the insulating substrate and the conductive polymer pillars of the present disclosure may both include a polymer material, so the anisotropic conductive film of the present disclosure has a good flexing resistance. Because the insulating substrate of the present disclosure may have an adhesive property, electronic devices (not shown) disposed on a top side and a lower side of the insulating substrate may be bonded to the insulating substrate in room temperature without need to perform a thermally curing process to fix the electronic devices.

While the disclosure has been described by way of example and in terms of the embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An anisotropic conductive film, comprising:
an insulating substrate having a first surface and a second surface; and
a plurality of conductive polymer pillars, wherein each of the conductive polymer pillars passes through the insulating substrate and is exposed at the first surface and the second surface, and the conductive polymer pillars include an intrinsically conducting polymer.

2. The anisotropic conductive film as claimed in claim 1, wherein the conductive polymer pillars further comprises a plurality of conductive particles doped in the intrinsically conducting polymer.

3. The anisotropic conductive film as claimed in claim 1, wherein the intrinsically conducting polymer comprises poly(3,4-ethylenedioxythiophene)-poly(styrenesulfonate), iodine doped trans polyacetylene, polyaniline, polypyrrole, polythiophene, or combinations thereof.

4. The anisotropic conductive film as claimed in claim 1, wherein a first end and a second end of each of the conductive polymer pillars respectively protrude from the first surface and the second surface.

5. The anisotropic conductive film as claimed in claim 1, wherein the insulating substrate comprises a glue with an adhesive property at room temperature.

6. The anisotropic conductive film as claimed in claim 5, wherein a first end and a second end of each of the conductive polymer pillars respectively protrude from the first surface and the second surface.

7. The anisotropic conductive film as claimed in claim 6, further comprising:
a first release film covering the first surface, wherein the first end of each of the conductive polymer pillars passes through the first release film.

8. The anisotropic conductive film as claimed in claim 6, further comprising:
a second release film covering the second surface, wherein the second end of each of the conductive polymer pillars passes through the second release film.

9. The anisotropic conductive film as claimed in claim 1, further comprising:
at least one first conductive pad disposed on the first surface and connecting to a plurality of first conductive polymer pillars of the conductive polymer pillars; and
at least one second conductive pad disposed on the second surface and connecting to the first conductive polymer pillars to electrically connect to the first conductive pad.

10. The anisotropic conductive film as claimed in claim 9, wherein the first conductive pad, the second conductive pad, and the first conductive polymer pillars are formed integrally, and the insulating substrate has a plurality of hollow through holes.

11. The anisotropic conductive film as claimed in claim 1, wherein a first end and a second end of each of the conductive polymer pillars are substantially aligned with the first surface and the second surface respectively.

12. The anisotropic conductive film as claimed in claim 1, wherein the insulating substrate comprises polymer materials.

13. The anisotropic conductive film as claimed in claim 1, wherein an aspect ratio of each of the conductive polymer pillars is larger than 1.

14. The anisotropic conductive film as claimed in claim 1, wherein the conductive particles comprise gold particles, silver particles, nickel particles, carbon black particles, graphite particles, carbon nanoballs, carbon nanotubes, or combinations thereof.

15. The anisotropic conductive film as claimed in claim 1, wherein major axis directions of the conductive polymer pillars are substantially parallel to a normal vector of the first surface or the second surface.

16. A manufacturing method of an anisotropic conductive film, comprising:
providing an insulating substrate having a first surface and a second surface;
forming a plurality of through holes in the insulating substrate, wherein each of the through holes passes through the first surface and the second surface;
filling a conductive polymer material in the through holes; and
curing the conductive polymer material to form a plurality of conductive polymer pillars in the through holes.

17. The manufacturing method of the anisotropic conductive film as claimed in claim 16, further comprising:
performing a screen printing process to form at least one first conductive pad and at least one second conductive pad on the first surface and the second surface respectively, wherein the first conductive pad electrically connects to the second conductive pad through a plurality of first conductive polymer pillars of the conductive polymer pillars.

18. The manufacturing method of the anisotropic conductive film as claimed in claim 17, wherein the screen printing process further comprises filling the conductive polymer material in the through holes.

19. The manufacturing method of the anisotropic conductive film as claimed in claim 16, further comprising:
applying a hydrophobic treatment to the first surface and the second surface before filling the conductive polymer material in the through holes.

20. The manufacturing method of the anisotropic conductive film as claimed in claim 16, wherein the insulating substrate comprises a glue with an adhesive property at room temperature, and the manufacturing method of the anisotropic conductive film further comprises:
respectively forming a first release film and a second release film on the first surface and the second surface before forming the through holes, wherein each of the through holes further passes through the first release film and the second release film during forming of the through holes in the insulating substrate.

21. The manufacturing method of the anisotropic conductive film as claimed in claim 20, further comprising:
removing the first release film and the second release film.

22. The manufacturing method of the anisotropic conductive film as claimed in claim 16, wherein the curing of the conductive polymer material comprises a thermal curing method or a light curing method.

23. The manufacturing method of the anisotropic conductive film as claimed in claim 16, wherein the forming of the through holes comprises energy beam drilling or machining.

24. The manufacturing method of the anisotropic conductive film as claimed in claim 23, wherein the energy beam drilling comprises laser beam drilling, electron beam drilling, or ion beam drilling.

25. An anisotropic conductive film, comprising:
an insulating substrate with an adhesive property at room temperature, wherein the insulating substrate has a first surface and a second surface; and
a plurality of conductive polymer pillars, wherein each of the conductive polymer pillars passes through the insulating substrate and is exposed at the first surface and the second surface, wherein the conductive polymer pillars are formed of an intrinsically conducting polymer or a composite conductive polymer comprising a plurality of conductive particles, and the conductive particles are gold particles, silver particles, nickel particles, carbon black particles, graphite particles, carbon nanotubes, or combinations thereof.
